(19) United States
(12) Patent Application Publication
(10) Pub. No.: US 2025/0079355 A1
(43) Pub. Date: Mar. 6, 2025

(54) SEMICONDUCTOR DEVICE AND METHOD OF MANUFACTURING THE SAME

(71) Applicant: SK hynix Inc., Icheon-si Gyeonggi-do (KR)

(72) Inventors: Woo Sung MOON, Icheon-si Gyeonggi-do (KR); Joon Seuk LEE, Icheon-si Gyeonggi-do (KR)

(73) Assignee: SK hynix Inc., Icheon-si Gyeonggi-do (KR)

(21) Appl. No.: 18/425,839

(22) Filed: Jan. 29, 2024

(30) Foreign Application Priority Data
Aug. 30, 2023 (KR) 10-2023-0114378

(51) Int. Cl. H01L 23/00; H01L 23/544

(52) U.S. Cl. CPC H01L 24/05; H01L 23/544; H01L 2223/54426; H01L 2223/5446; H01L 2224/05554; H01L 2924/1304

(57) ABSTRACT

Provided herein may be a semiconductor device and a method of manufacturing the same. The semiconductor device may include a first structure including a first chip area and a first scribe lane area, a second structure provided on the first structure, a first alignment key disposed in the first scribe lane area, at least one first bonding pad provided between the first alignment key and the first chip area, the first bonding pad bordering an upper surface of the first structure, and a second bonding pad bordering a lower surface of the second structure to contact the at least one first bonding pad.

### CROSS-REFERENCE TO RELATED APPLICATION

The present application claims priority under 35 U.S.C. § 119(a) to Korean patent application number 10-2023-0114378 filed on Aug. 30, 2023, in the Korean Intellectual Property Office, the entire disclosure of which is incorporated by reference herein.

### BACKGROUND

### 1. Technical Field

Various embodiments of the present disclosure generally relate to a semiconductor device and a method of manufacturing the semiconductor device, and more particularly to a semiconductor device including a memory block with a three-dimensional (3D) structure and a method of manufacturing the semiconductor device.

### 2. Related Art

Through a semiconductor integration process, multiple chip areas may be formed on a semiconductor substrate. The multiple chip areas may be separated from each other by scribe lane areas. By separating the semiconductor chip areas from each other through a cutting process, the semiconductor chip areas may be manufactured into multiple semiconductor chips.

As an improvement in integration degree of two-dimensional (2D) nonvolatile memory device that forms memory cells in a single layer on a substrate reaches its limit, a nonvolatile memory device with a 3D structure that vertically stacks memory cells on the substrate has been proposed, and a method of forming more circuits in a limited chip area has been proposed. For example, there has been proposed a wafer bonding method that combines a first wafer on which a peripheral circuit is formed and a second wafer on which memory cells are formed.

### SUMMARY

An embodiment of the present disclosure may provide for a semiconductor device. The semiconductor device may include a first structure including a first chip area and a first scribe lane area, a second structure provided on the first structure, a first alignment key disposed in the first scribe lane area, at least one first bonding pad disposed in the first scribe lane area, provided between the first alignment key and the first chip area, the first bonding pad bordering an upper surface of the first structure, and at least one second bonding pad bordering to a lower surface of the second structure to contact the at least one first bonding pad.

An embodiment of the present disclosure may provide for a method of manufacturing a semiconductor device. The method may include forming a first alignment key in a first scribe lane area of a first structure in which the first scribe lane area and a first chip area are defined, forming at least one first bonding pad that is provided between the first alignment key and the first chip area, the at least one first bonding pad bordering an upper surface of the first structure, forming at least one second bonding pad that borders an upper surface of a second structure, the at least one second bonding pad formed in a second scribe lane area of the second structure in which the second scribe lane area and a second chip area are defined, and flipping the second structure so that the at least one second bonding pad borders a lower surface of the second structure and stacking the second structure on the first structure so that the at least one second bonding pad of the flipped second structure contacts the at least one first bonding pad.

### BRIEF DESCRIPTION OF THE DRAWINGS

FIG. 1 is a view illustrating the structure of a semiconductor device according to an embodiment of the present disclosure.

FIG. 2 is a sectional view illustrating the structure of the semiconductor device according to an embodiment of the present disclosure.

FIGS. 3A to 3C are views illustrating an alignment key and bonding pads according to an embodiment of the present disclosure.

FIGS. 4A to 4E are views illustrating various shapes of bonding pads according to an embodiment of the present disclosure.

FIGS. 5A to 5H are views illustrating a method of manufacturing a semiconductor device according to an embodiment of the present disclosure.

FIG. 6 is a diagram illustrating a memory card system to which the semiconductor device of the present disclosure is applied.

FIG. 7 is a diagram illustrating a solid state drive (SSD) system to which the semiconductor device of the present disclosure is applied.

### DETAILED DESCRIPTION

Specific structural or functional descriptions in the embodiments of the present disclosure introduced in this specification or application are only for description of the embodiments of the present disclosure. The present disclosure may be embodied in many different forms and should not be construed as being limited to the embodiments described in the specification or application.

Hereinafter, the embodiments of the present disclosure will be described with reference to the accompanying drawings to the extent that a person skilled in the art to which the present disclosure pertains can easily practice the technical spirit of the present disclosure.

Various embodiments of the present disclosure are directed to a semiconductor device and a method of manufacturing the semiconductor device that can increase the bonding force of the semiconductor device manufactured in a wafer bonding method.

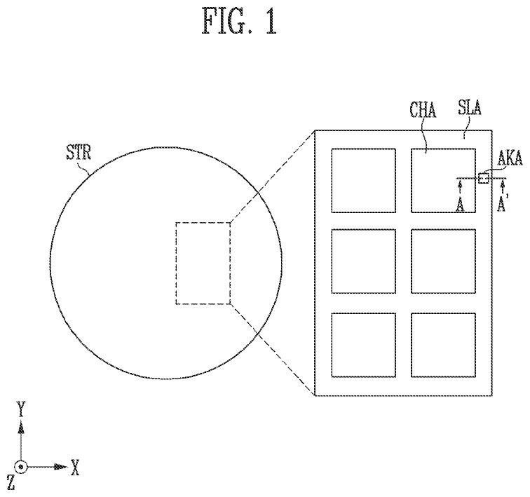

FIG. 1 is a view illustrating the structure of a semiconductor device according to an embodiment of the present disclosure.

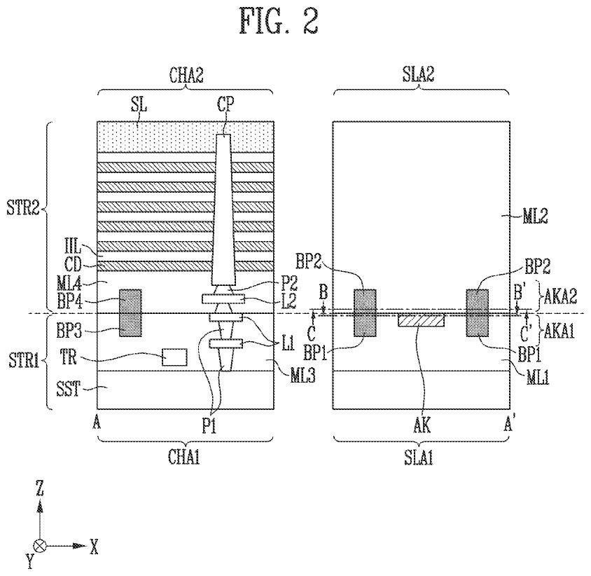

The semiconductor device may include a structure STR. For example, the semiconductor device may include two structures STR. The structure STR may include a substrate (e.g., silicon wafer, SiGe wafer, SOI wafer) and material patterns formed on the substrate. In another embodiment, the structure STR may include material patterns and might not include a substrate. The cross-sectional shape of the structure STR will be described later with reference to FIG. 2.

Referring to FIG. 1, the structure STR may include chip areas CHA and a scribe lane area SLA. The scribe lane area SLA may enclose the chip areas CHA.

The chip areas CHA may be areas in which semiconductor chips are formed. The chip areas CHA may be arranged in an X-Y plane. Through a semiconductor integration process performed on the chip areas CHA, the semiconductor chips may be formed. The semiconductor chips formed in the plurality of chip areas CHA may be substantially the same. After the semiconductor integration process is completed on the substrate, the structure STR may be separated into the chip areas CHA so that each of the chip areas CHA may be separated into the shape of the semiconductor chip.

The scribe lane area SLA may be disposed outside of the chip areas CHA. For example, the scribe lane area SLA may be disposed between the chip areas CHA. After the semiconductor integration process is completed, the scribe lane area SLA may be cut off during a dicing process that separates the semiconductor chips. Each of the chip areas CHA may be separated by cutting the structure STR along the scribe lane area SLA. The process for cutting the structure STR may include a sawing process using a blade, a laser process using a laser, a stealth dicing process, or the like. A chip guard that protects the chip areas CHA, an electrical test pattern, a process monitoring pattern, and an alignment key may be disposed in the scribe lane area SLA.

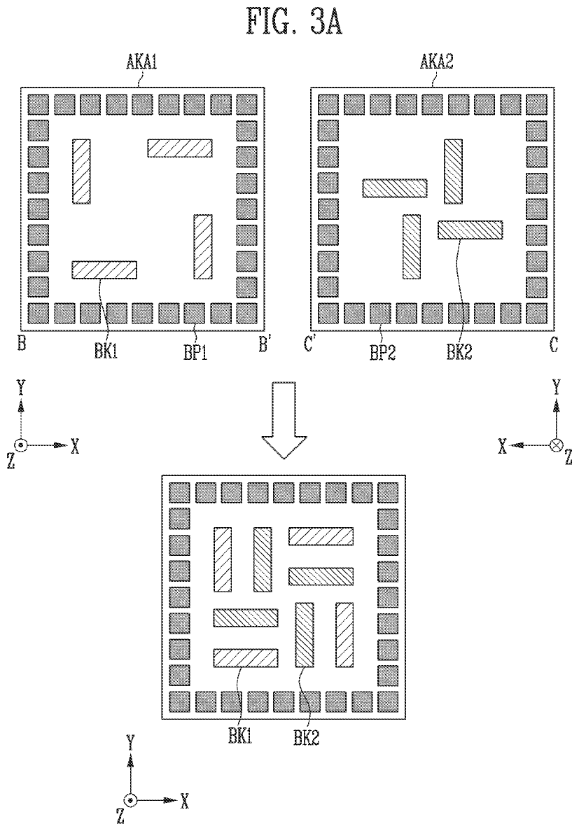

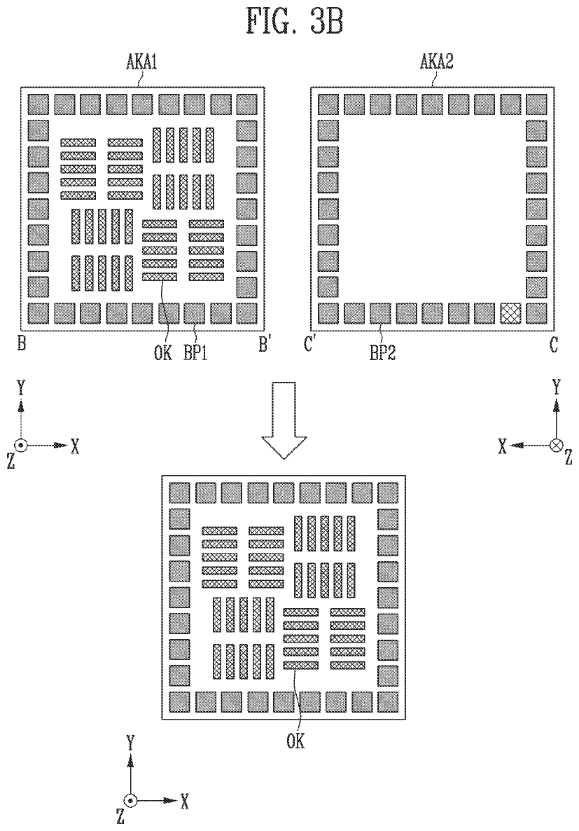

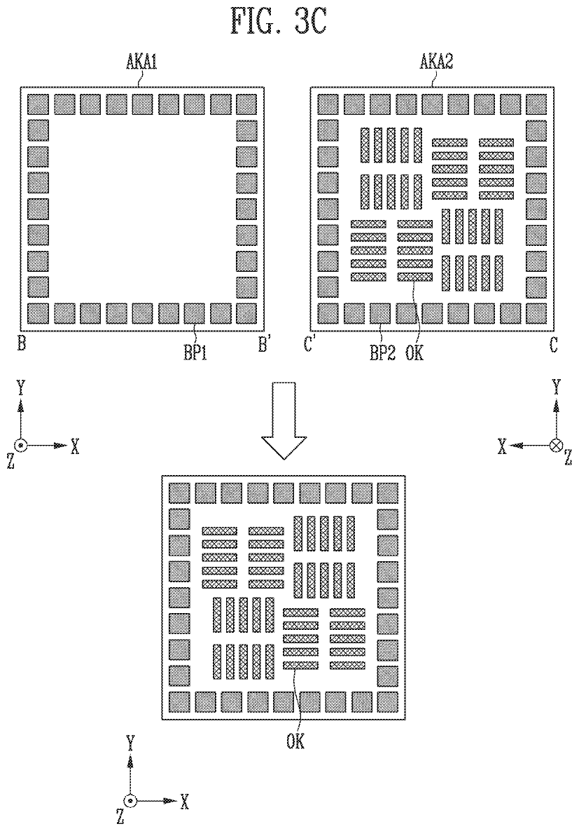

An alignment key area AKA may be defined in an area of the scribe lane area SLA. The alignment key area AKA may be an area in which alignment keys are formed. The alignment key will be described later with reference to FIGS. 3A to 3C.

Although FIG. 1 shows six chip areas CHA, this is merely for convenience of explanation, and it is not limited thereto. For example, the structure STR may include a varying number of chip areas CHA, which includes 7 or more. In addition, although FIG. 1 shows that the scribe lane area SLA includes one alignment key area AKA, it is not limited thereto. The position and number of alignment key areas AKA included in the scribe lane area SLA may be changed in various ways. Furthermore, the alignment key area AKA may be formed at any position around the chip area CHA, and at least two alignment key areas AKA may be disposed adjacent to any one chip area CHA.

FIG. 2 is a sectional view illustrating the structure of the semiconductor device according to an embodiment of the present disclosure. FIG. 2 is a sectional view taken along line A-A′ of FIG. 1.

Referring to FIG. 2, the semiconductor device may include a first structure STR1 and a second structure STR2, the second structure STR2 being provided on the first structure STR1 in a Z direction. The second structure STR2 may be stacked on the first structure STR1. A lower surface of the second structure STR2 may contact an upper surface of the first structure STR1. The second structure STR2 may be coupled to the first structure STR1 through a wafer bonding method.

The first structure STR1 may include a first chip area CHA1 and a first scribe lane area SLA1. The second structure STR2 may include a second chip area CHA2 and a second scribe lane area SLA2. The second chip area CHA2 may overlap with the first chip area CHA1, and the second scribe lane area SLA2 may overlap with the first scribe lane area SLA1. Each of the first chip area CHA1 and the second chip area CHA2 may correspond to the chip area CHA of FIG. 1, and each of the first scribe lane area SLA1 and the second scribe lane area SLA2 may correspond to the scribe lane area SLA of FIG. 1. Although FIG. 2 shows that the scribe lane area (e.g., SLA1, SLA2) is disposed in the X direction in relation to the chip area (e.g., CHA1, CHA2), this is merely illustrative and is not limited thereto. For example, the scribe lane area (e.g., SLA1, SLA2) may be disposed in various directions in relation to the chip area (e.g., CHA1, CHA2), such as the Y direction, the opposite direction of the X direction, or the opposite direction of the Y direction.

The first structure STR1 may include a substrate SST. The substrate SST may extend from the first chip area CHA1 to the first scribe lane area SLA1. The substrate SST may extend in the X direction and the Y direction. For example, the substrate SST may be a silicon wafer, a SiGe wafer, or a SOI wafer.

The first structure STR1 may include a first material layer ML1 disposed on the substrate SST. The first material layer ML1 may be formed in the first scribe lane area SLA1 of the first structure STR1. The first material layer ML1 may be formed as an insulating layer (e.g., oxide layer).

Further, the first structure STR1 may include a peripheral circuit. The first structure STR1 may include a third material layer ML3 disposed on the substrate SST and may include at least one transistor TR, at least one first line L1, and at least one first plug P1 disposed inside the third material layer ML3. The third material layer ML3, at least one transistor TR, at least one first line L1, and at least one first plug P1 may be formed in the first chip area CHA1 of the first structure STR1. The third material layer ML3 may be formed as an insulating layer (e.g., oxide layer), at least one transistor TR may be formed of a semiconductor layer (e.g., doped silicon), and at least one first line L1 and at least one first plug P1 may be formed of a conductive layer (e.g., metal). The transistor TR, the first line L1, and the first plug P1, shown in FIG. 2, are merely illustrative. The first structure STR1 may include additional components as along with the transistor TR, the first line L1, and the first plug P1, shown in FIG. 2, to form the peripheral circuit.

The second structure STR2 may include a second material layer ML2 overlapping with the first material layer ML1. The second material layer ML2 may be formed in the second scribe lane area SLA2 of the second structure STR2. The second material layer ML2 may be formed as a single layer or a multilayer. For example, the second material layer ML2 may be formed as the insulating layer (e.g., oxide layer). In another embodiment, some areas of the second material layer ML2 may be formed as the insulating layer, while other areas may be formed of a plurality of layers having different characteristics.

Further, the second structure STR2 may include conductive layers CD and interlayer insulating layers IIL that are alternately stacked. The conductive layers CD and the interlayer insulating layers IIL may be formed in the second chip area CHA2 of the second structure STR2. The conductive layers CD and the interlayer insulating layers IIL may be stacked on each other in the Z direction. The conductive layers CD may be formed of at least one of tungsten (W), cobalt (Co), nickel (Ni), molybdenum (Mo), silicon (Si), and poly-silicon (poly-Si). The interlayer insulating layers IIL may be formed as the insulating layer (e.g., oxide layer).

The second structure STR2 may include a cell plug CP within the conductive layers CD and the interlayer insulating layers IIL that are alternately stacked. The cell plug CP may be formed in the second chip area CHA2 of the second structure STR2. The cell plug CP may extend in the Z direction. The cell plug CP may penetrate the conductive layers CD and the interlayer insulating layers IIL that are alternately stacked. The cell plug CP may protrude farther in the Z direction than the uppermost interlayer insulating layer IIL, among the conductive layers CD and the interlayer insulating layers IIL that are alternately stacked. Although one cell plug CP is shown in FIG. 2, the second structure STR2 may include two or more cell plugs CP. Although not shown in the drawing, the cell plug CP may include at least some of a blocking layer, a charge trap layer formed along an inner wall of the blocking layer, a tunnel isolation layer formed along an inner wall of the charge trap layer, a channel layer formed along an inner wall of the tunnel isolation layer, and a core pillar that fills the inside of the channel layer.

The second structure STR2 may include a source layer SL on the conductive layers CD and the interlayer insulating layers IIL that are alternately stacked. The source layer SL may be formed on the second chip area CHA2 of the second structure STR2. The source layer SL may enclose a portion of the cell plug CP that protrudes farther in the Z direction than the interlayer insulating layer IIL. That is, the cell plug CP may protrude into the source layer SL. The source layer SL may be formed of doped silicon.

The second structure STR2 may include a fourth material layer ML4 under the conductive layers CD and the interlayer insulating layers IIL that are alternately stacked. The fourth material layer ML4 may overlap with the third material layer ML3 of the first structure STR1. The fourth material layer ML4 may be formed as an insulating layer (e.g., oxide layer).

The second structure STR2 may include at least one second line L2 and at least one second plug P2, which are coupled to the cell plug CP. For example, the second line L2 may be a bit line. At least one second line L2 and at least one second plug P2 may be formed in the fourth material layer ML4. The second plug P2 may be electrically connected to the first plug P1. For example, the second plug P2 may directly contact the first plug P1, or the second plug may be indirectly coupled to the first plug through a separate path.

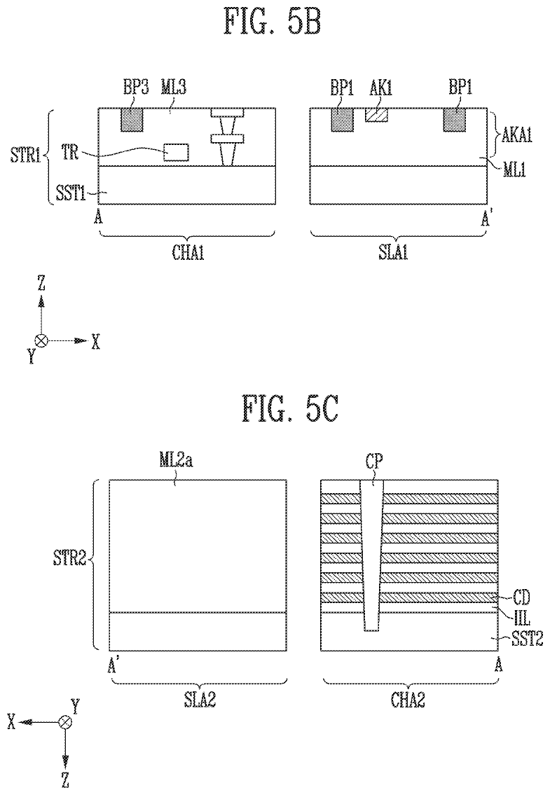

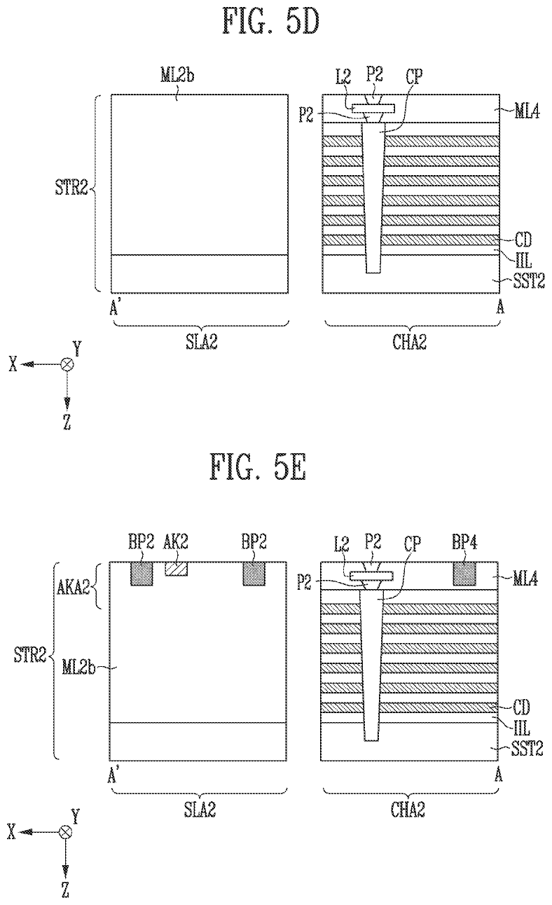

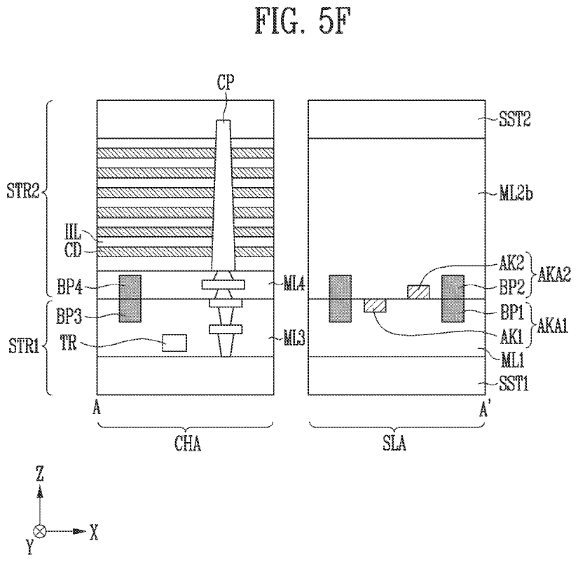

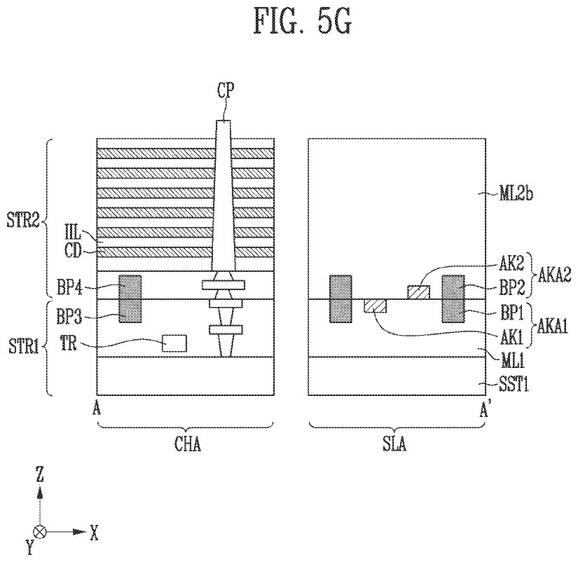

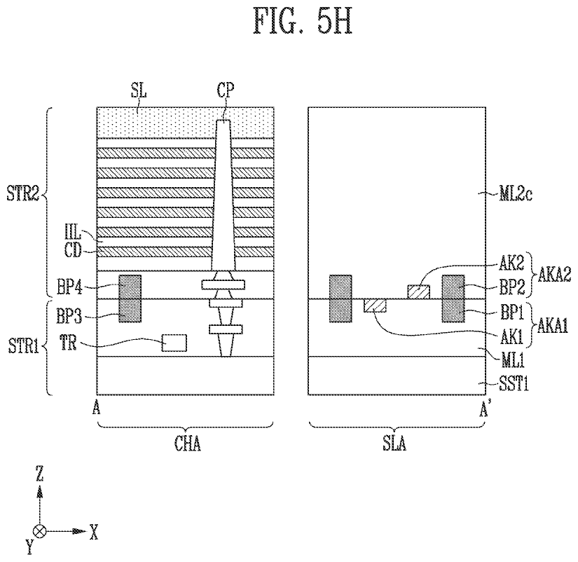

The second structure STR2 might not include the substrate. The second structure STR2 having no substrate will be described later with reference to FIGS. 5C to 5H.

Referring to FIG. 2, the semiconductor device may include an alignment key AK. The alignment key AK may be disposed in the scribe lane area SLA of the semiconductor device. For example, the alignment key AK may be disposed in the scribe lane area SLA1 of the first structure STR1. The alignment key AK may be disposed in a first alignment key area AKA1 of the first scribe lane area SLA1. The alignment key AK may border an upper surface of the first structure STR1. The alignment key AK may contact the second material layer ML2, the second material layer ML2 bordering a lower surface of the second structure STR2. The alignment key AK may be formed of a material that is different from that of the first material layer ML1. For example, the alignment key AK may include a metal material, such as tungsten.

Although FIG. 2 shows that the alignment key AK is formed in the first scribe lane area SLA1 of the first structure STR1, it is merely illustrative and is not limited thereto. For example, the alignment key AK may be formed in the second scribe lane area SLA2, instead of the first scribe lane area SLA1. In another embodiment, the first alignment key may be formed in the first scribe lane area SLA1, and a second alignment key may be formed in the second scribe lane area SLA2. Various embodiments of the alignment key AK being formed in different positions will be described later with reference to FIGS. 3A to 3C.

The semiconductor device may include at least one first bonding pad BP1 disposed between the alignment key AK and the chip area CHA. The first bonding pad BP1 may be disposed in the first scribe lane area SLA1 of the first structure STR1. The first bonding pad BP1 may be disposed between the alignment key AK and the first chip area CHA1. The first bonding pad BP1 may be disposed in the first alignment key area AKA1 of the first scribe lane area SLA1. The first bonding pad BP1 may be spaced apart from the alignment key AK. The first bonding pad BP1 may border the upper surface of the first structure STR1. The first structure STR1 may include one first bonding pad BP1 or two or more first bonding pads BP1. The first bonding pad BP1 may be formed of a material that is to the same as or different from that of the alignment key AK. For example, the first bonding pad BP1 may be formed of a metal material, such as copper (Cu).

The semiconductor device may include a second bonding pad BP2 contacting the first bonding pad BP1. The second bonding pad BP2 may be disposed in the second scribe lane area SLA2 of the second structure STR2. The second bonding pad BP2 may be disposed in a second alignment key area AKA2 of the second scribe lane area SLA2. The second bonding pad BP2 may border the lower surface of the second structure STR2. The second bonding pad BP2 may overlap with the first bonding pad BP1. The second structure STR2 may include one second bonding pad BP2 or two or more second bonding pads BP2.

The second bonding pad BP2 may be formed of the same material as that of the first bonding pad BP1. For example, the second bonding pad BP2 may be formed of a metal material, such as copper (Cu). Since the first bonding pad BP1 and the second bonding pad BP2 include the same material, a bonding force between the first bonding pad BP1 and the second bonding pad BP2 may be relatively high. For example, compared to the bonding force between the alignment key AK and the second material layer ML2, which include different materials, the bonding force between the first bonding pad BP1 and the second bonding pad BP2 including the same material may be higher. In another example, compared to the bonding force between the first material layer ML1 and the second material layer ML2 formed of an insulating layer, the bonding force between the first bonding pad BP1 and the second bonding pad BP2 formed of a metal material may be higher.

The semiconductor device may include a third bonding pad BP3 that is disposed in the first chip area CHA1 of the first structure STR1. The third bonding pad BP3 may border the upper surface of the first structure STR1. Further, the semiconductor device may include a fourth bonding pad BP4 disposed in the second chip area CHA2 of the second structure STR2. The fourth bonding pad BP4 may border the lower surface of the second structure STR2. The fourth bonding pad BP4 may contact the third bonding pad BP3. The fourth bonding pad BP4 may contact the third bonding pad BP3.

The first bonding pad BP1 and the third bonding pad BP3 may be formed of the same material. For example, the first bonding pad BP1 and the third bonding pad BP3 may be simultaneously formed. Further, the second bonding pad BP2 and the fourth bonding pad BP4 may be formed of the same material. For example, the second bonding pad BP2 and the fourth bonding pad BP4 may be simultaneously formed.

According to the present disclosure, since the semiconductor device includes the first and second bonding pads BP1 and BP2 formed in the scribe lane areas SLA1 and SLA2 as well as the third and fourth bonding pads BP3 and BP4 formed in the chip areas CHA1 and CHA2, the bonding force between the first and second structures STR1 and STR2 may increase compared to a case in which the first and second bonding pads BP1 and BP2 are not included. Therefore, delamination occurring in the area (e.g., alignment key area AKA1 or AKA2) in which the alignment key AK is formed may be reduced.

FIGS. 3A to 3C are views illustrating the alignment key and the bonding pads according to an embodiment of the present disclosure. FIGS. 3A to 3C are a section taken along line B-B′ of FIG. 2, a section taken along line C-C′ of FIG. 2, and a view showing a state in which the section of B-B′ and the section of C-C′ are combined, respectively.

Referring to FIG. 3A, the alignment key AK of FIG. 2 may be bonding keys BK1 and BK2. The bonding keys BK1 and BK2 may be pattern structures formed to align the second structure STR2 on the first structure STR1. For example, in order to superpose the second chip area CHA2 on the first chip area CHA1 and to superpose the second scribe lane area SLA2 on the first scribe lane area SLA1, the bonding keys BK1 and BK2 may be used.

When the alignment key AK is the bonding key BK1 or BK2, the first bonding key BK1 may be formed in the first alignment key area AKA1 of the first structure STR1, and the second bonding key BK2 may be formed in the second alignment key area AKA2 of the second structure STR2. The first bonding key BK1 may border the upper surface of the first structure STR1, and the second bonding key BK2 may border the lower surface of the second structure STR2. The first bonding key BK1 and the second bonding key BK2 might not overlap with each other. For example, when the first structure STR1 and the second structure STR2 are coupled to each other, the first bonding key BK1 and the second bonding key BK2 may be spaced apart from each other.

Referring to FIGS. 3B and 3C, the alignment key AK of FIG. 2 may be an overlay key OK. The overlay key OK may be a pattern structure formed for alignment between a photomask and the first structure STR1 or between the photomask and the second structure STR2 in a lithography step of the semiconductor integration process. For instance, the overlay key OK may be used to form at least one of cell plugs, contact plugs, bit lines, and slit insulating layers of the semiconductor chip. However, without being limited thereto, the overlay key OK may be used to form various structures in the semiconductor chip.

When the alignment key AK is the overlay key OK, as shown in FIG. 3B, the overlay key OK may be formed in the first alignment key area AKA1 of the first structure STR1, and the overlay key OK might not be formed in the second alignment key area AKA2 of the second structure STR2. Alternatively, when the alignment key AK is the overlay key OK, as shown in FIG. 3C, the overlay key OK might not be formed in the first alignment key area AKA1 of the first structure STR1, and the overlay key OK may be formed in the second alignment key area AKA2 of the second structure STR2. That is, the overlay key OK may be formed in any one of the first alignment key area AKA1 and the second alignment key area AKA2 that overlap with each other. For example, the overlay key OK (see FIG. 3B) used to form the first structure STR1 and the overlay key OK (see FIG. 3C) used to form the second structure STR2 may be formed in an area in which the second structure STR2 does not overlap with the first structure STR1 while being stacked thereon. The overlay key OK of FIG. 3B may border the upper surface of the first structure STR1. The overlay key OK of FIG. 3C may border the lower surface of the second structure STR2.

In the present disclosure, the alignment key (e.g., the first bonding key BK1 of FIG. 3A and the overlay key OK of FIG. 3B) disposed in the first alignment key area AKA1 of the first structure STR1 may be referred to as a first alignment key. Further, the alignment key (e.g., the second bonding key BK2 of FIG. 3A and the overlay key OK of FIG. 3C) disposed in the second alignment key area AKA2 of the second structure STR2 may be referred to as a second alignment key. In the present disclosure, the cross-sectional shapes of the first alignment key and the second alignment key are not limited to those shown in FIGS. 3A to 3C.

Referring to FIGS. 3A to 3C, at least one first bonding pad BP1 may be disposed between the first alignment key (e.g., the first bonding key BK1 of FIG. 3A and the overlay key OK of FIG. 3B) and the first chip area CHA1. The first bonding pads BP1 may be spaced apart from the first alignment key. The first bonding pads BP1 may be disposed in at least one direction from the first alignment key: the X direction, the Y direction, the opposite direction of the X direction, and the opposite direction of the Y direction. The first bonding pads BP1 may be adjacent to a boundary of the first alignment key area AKA1. The first bonding pads BP1 disposed in the first alignment key area AKA1 may be referred to as a first bonding pad group. The first bonding pads BP1 included in the first bonding pad group may enclose the periphery of the first alignment key.

The second bonding pads BP2 may be formed at positions corresponding to the first bonding pads BP1. For example, the second bonding pads BP2 may be formed to overlap with the first bonding pads BP1 while the second structure STR2 is stacked on the first structure STR1. At least one second bonding pad BP2 may be disposed between the second alignment key (e.g., the second bonding key BK2 of FIG. 3A and the overlay key OK of FIG. 3C) and the second chip area CHA2. The second bonding pads BP2 may be spaced apart from the second alignment key. The second bonding pads BP2 may be disposed in at least one direction from the second alignment key: the X direction, the Y direction, the opposite direction of the X direction, and the opposite direction of the Y direction. The second bonding pads BP2 may be adjacent to a boundary of the second alignment key area AKA2. The second bonding pads BP2 disposed in the second alignment key area AKA2 may be referred to as a second bonding pad group. The second bonding pads BP2 included in the second bonding pad group may be disposed along the border of the second alignment key.

According to the present disclosure, the bonding force between the first and second structures STR1 and STR2 may be increased by the first and second bonding pads BP1 and BP2 formed in the first and second alignment key areas AKA1 and AKA2. For instance, referring to FIGS. 2 and 3A, since the first bonding key BK1 contacts the second material layer ML2, the second bonding key BK2 contacts the first material layer ML1, and the first and second bonding keys BK1 and BK2 and the first and second material layers ML1 and ML2 are formed of different materials, the bonding force at a heterogeneous junction surface may be weak. Further, referring to FIGS. 2 and 3B, since the overlay key OK contacts the second material layer ML2 and the overlay key OK and the second material layer ML2 are formed of different materials, the bonding force at the heterogeneous junction surface may be weak. In the present disclosure, the heterogeneous junction surface may refer to an interface between material layers including different materials. However, since the semiconductor device of the present disclosure includes the first and second bonding pads BP1 and BP2 formed of the same material (e.g., metal), the sectional area of the homogeneous junction surface may be increased, thereby increasing the bonding force between the first and second structures STR1 and STR2. In the present disclosure, the homogeneous junction surface may refer to an interface between the material layers including the same material.

According to the present disclosure, a dishing phenomenon occurring in the first and second alignment key areas AKA1 and AKA2 during the CMP process may be prevented or reduced by the first and second bonding pads BP1 and BP2. That is, a step between the joint surfaces of the first and second structures STR1 and STR2 may be removed or reduced by the first and second bonding pads BP1 and BP2. Therefore, the first and second bonding pads BP1 and BP2 may further increase the bonding force between the first and second structures STR1 and STR2.

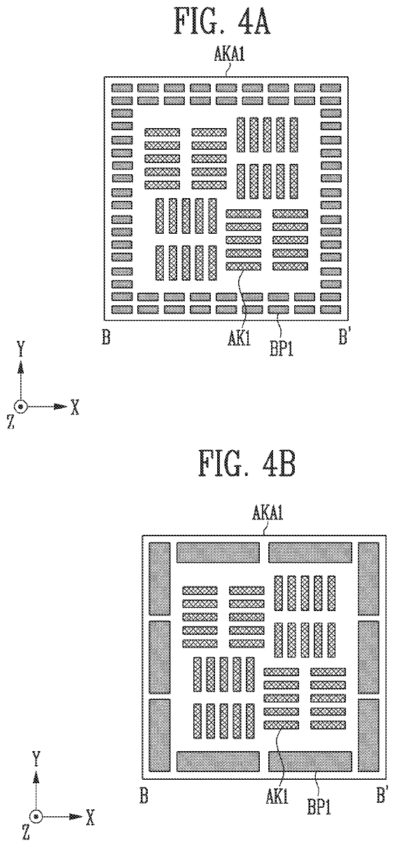

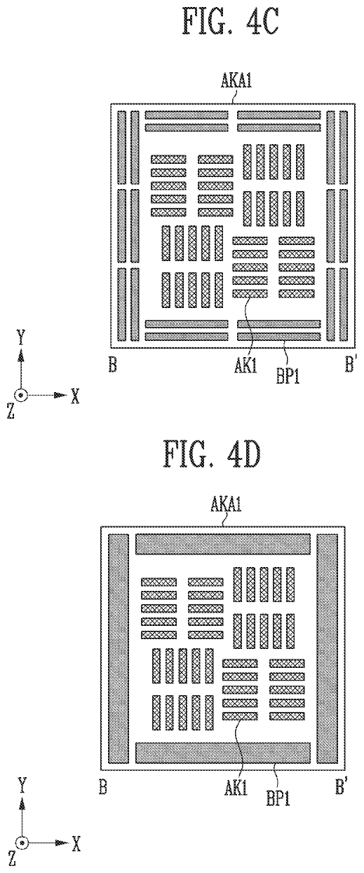

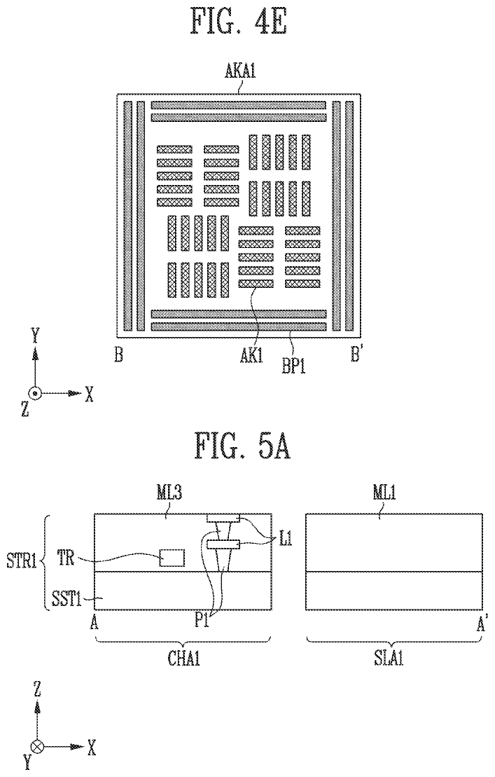

Referring to FIGS. 3A to 3C, each of the first and second bonding pads BP1 and BP2 may have a square sectional shape. Further, the first and second bonding pads BP1 and BP2 may be aligned along the boundaries of the first and second alignment key areas AKA1 and AKA2, respectively. However, the cross-sectional shape and arrangement method of the first and second bonding pads BP1 and BP2 are not limited to those shown in FIGS. 3A to 3C. FIGS. 4A to 4E show various embodiments of the cross-sectional shape and arrangement method of the first and second bonding pads BP1 and BP2.

FIGS. 4A to 4E are views illustrating various shapes of bonding pads according to an embodiment of the present disclosure.

FIGS. 4A to 4E show the first alignment key AK1 and the first bonding pads BP1 formed in the first alignment key area AKA1. Since the second bonding pads BP2 of the second alignment key area AKA2 are formed to correspond to the first bonding pads BP1, the second alignment key area AKA2 has been omitted in FIGS. 4A to 4E. Further, FIGS. 4A to 4E show the overlay key OK of FIG. 3B as an example of the first alignment key AK1, but it may be replaced with another alignment key as shown in FIG. 3A or 3C. Hereinafter, various cross-sectional shapes and arrangement methods of the first bonding pads BP1 will be described with reference to FIGS. 4A to 4E.

Referring to FIG. 4A, each of the first bonding pads BP1 may have a rectangular cross-section where the X-direction length is longer than the Y-direction length. For example, the X-direction length of each of the first bonding pads BP1 in FIG. 4A may be the same as that of each of the first bonding pads BP1 in FIGS. 3A to 3C, and the Y-direction length of each of the first bonding pads BP1 in FIG. 4A may be less than ½ of that of each of the first bonding pads BP1 in FIGS. 3A to 3C. Further, the number of the first bonding pads BP1 in FIG. 4A may be approximately twice that of the first bonding pads BP1 in FIGS. 3A to 3C. Furthermore, referring to FIG. 4A, the first bonding pads BP1 may be arranged in a row along the boundary of the first alignment key area AKA1 in the X direction (i.e., the right and left surfaces) and may be double-arranged along the boundary of the first alignment key area AKA1 in the Y direction (i.e., the top and bottom surfaces).

Referring to FIG. 4B, some of the first bonding pads BP1 may have a rectangular cross-section where the X-direction length is longer than the Y-direction length, and others may have a rectangular cross-section where the Y-direction length is longer than the X-direction length. For example, a long side of each of the first bonding pads BP1 in FIG. 4B may be longer in length than that of each of the first bonding pads BP1 in FIGS. 3A to 3C, and a short side of each of the first bonding pads BP1 in FIG. 4B may have the same length as each of the first bonding pads BP1 in FIGS. 3A to 3C. Further, the number of the first bonding pads BP1 in FIG. 4B may be less than that of the first bonding pads BP1 in FIGS. 3A to 3C. Furthermore, the first bonding pads BP1 in FIG. 4B may be arranged in a row along the boundary of the first alignment key area AKA1.

Referring to FIG. 4C, some of the first bonding pads BP1 may have a rectangular cross-section where the X-direction length is longer than the Y-direction length, and others may have a rectangular cross-section where the Y-direction length is longer than the X-direction length. For example, a long side of each of the first bonding pads BP1 in FIG. 4C may be longer in length than that of each of the first bonding pads BP1 in FIGS. 3A to 3C, and a short side of each of the first bonding pads BP1 in FIG. 4C may be shorter in length than that of each of the first bonding pads BP1 in FIGS. 3A to 3C. Further, the number of the first bonding pads BP1 in FIG. 4C may be approximately twice that of the first bonding pads BP1 in FIG. 4B. Furthermore, the first bonding pads BP1 in FIG. 4C may be double-arranged along the boundary of the first alignment key area AKA1.

Referring to FIG. 4D, some of the first bonding pads BP1 may have a rectangular cross-section where the X-direction length is longer than the Y-direction length, and others may have a rectangular cross-section where the Y-direction length is longer than the X-direction length. For example, a long side of each of the first bonding pads BP1 in FIG. 4D may be longer in length than that of each of the first bonding pads BP1 in FIG. 4B. Further, the number of the first bonding pads BP1 in FIG. 4D may be less than that of the first bonding pads BP1 in FIG. 4B. Furthermore, the first bonding pads BP1 in FIG. 4D may be arranged along the boundary of the first alignment key area AKA1 in each direction.

Referring to FIG. 4E, some of the first bonding pads BP1 may have a rectangular cross-section where the X-direction length is longer than the Y-direction length, and others may have a rectangular cross-section where the Y-direction length is longer than the X-direction length. For example, a long side of each of the first bonding pads BP1 in FIG. 4E may have the same length as that of each of the first bonding pads BP1 in FIG. 4D, and a short side of each of the first bonding pads BP1 in FIG. 4E may be shorter in length than that of each of the first bonding pads BP1 in FIG. 4D. Further, the number of the first bonding pads BP1 in FIG. 4E may be less than that of the first bonding pads BP1 in FIG. 4C. Furthermore, the first bonding pads BP1 in FIG. 4E may be double-arranged along the boundary of the first alignment key area AKA1 in each direction.

The cross-sectional shape, number, and arrangement method of the first bonding pads BP1 shown in FIGS. 4A to 4E are some of various embodiments of the present disclosure, and the first bonding pads BP1 may be formed in various ways in addition to the embodiments shown in FIGS. 4A to 4E.

FIGS. 5A to 5H are views illustrating a method of manufacturing a semiconductor device according to an embodiment of the present disclosure. FIGS. 5A to 5H each may correspond to the cross-section taken along line A-A′ of FIG. 2.

Referring to FIG. 5A, a first structure STR1 may include a first scribe lane area SLA1 and a first chip area CHA1. The first structure STR1 may include a first substrate SST1. In the first scribe lane area SLA1 of the first structure STR1, a first material layer ML1 may be formed on the first substrate SST1. In the first chip area CHA1 of the first structure STR1, a third material layer ML3 may be formed on the first substrate SST1. The first material layer ML1 and the third material layer ML3 may be simultaneously formed or may be formed through separate processes.

At least one transistor TR, at least one first line L1, and at least one first plug P1 may be formed in the first chip area CHA1 of the first structure STR1. At least one first line L1 and at least one first plug P1 may be formed in the third material layer ML3.

Referring to FIG. 5B, a first alignment key AK1 may be formed in the first scribe lane area SLA1 of the first structure STR1. For example, the first alignment key AK1 may be formed in the first alignment key area AKA1 of the first scribe lane area SLA1. The first alignment key AK1 may be the first bonding key BK1 of FIG. 3A.

At least one first bonding pad BP1 may be formed between the first alignment key AK1 and the first chip area CHA1. The first bonding pads BP1 may border the upper surface of the first structure STR1. The first bonding pads BP1 may be formed in the first scribe lane area SLA1 of the first structure STR1. For example, a portion of the upper surface of the first material layer ML1 may be etched to form trenches, and the interior of the trenches may be filled with a metal layer to form the first bonding pads BP1. An anisotropic dry etching process may be performed to form the trenches at designated positions on the first material layer ML1.

A third bonding pad BP3 may be formed in the first chip area CHA1 of the first structure STR1. The third bonding pad BP3 may border the upper surface of the first structure STR1. For example, a portion of the upper surface of the third material layer ML3 may be etched to form trenches, and the interior of the trenches may be filled with a metal layer to form the third bonding pad BP3.

In an embodiment, the first bonding pads BP1 and the third bonding pad BP3 may be simultaneously formed. In an embodiment, the first bonding pads BP1 and the third bonding pad BP3 may be formed through different processes.

Referring to FIG. 5C, a second structure STR2 may include a second scribe lane area SLA2 and a second chip area CHA2. In FIG. 5C, the second structure STR2 may include a second substrate SST2. In the second chip area CHA2 of the second structure STR2, conductive layers CD, interlayer insulating layers IIL, and a cell plug CP may be formed on the second substrate SST2. For example, the interlayer insulating layers IIL and sacrificial layers (not shown) may be alternately stacked on the second substrate SST2, the cell plug CP may be formed to penetrate the interlayer insulating layers IIL and the sacrificial layers, and the sacrificial layers may be replaced with conductive layers CD. The cell plug CP may protrude into the second substrate SST2.

In the second scribe lane area SLA2 of the second structure STR2, the second material layer ML2a may be formed on the second substrate SST2. The second material layer ML2a may be formed as a single layer (e.g., insulating layer), include the interlayer insulating layers IIL and the conductive layers CD that are alternately stacked, or include the interlayer insulating layers IIL and the sacrificial layers that are alternately stacked.

Referring to FIG. 5D, a fourth material layer ML4 may be formed in the second chip area CHA2 of the second structure STR2. A fourth material layer ML4 may be formed on the conductive layers CD and the interlayer insulating layers IIL that are alternately stacked. Further, at least one second line L2 and at least one second plug P2 may be formed in the fourth material layer ML4. The second line L2 may be electrically connected to the cell plug CP.

Further, a second material layer ML2b may be formed in the second scribe lane area SLA2 of the second structure STR2. For example, a material layer identical to the fourth material layer ML4 may be formed on the second material layer ML2a of FIG. 5C to form a second material layer ML2b of FIG. 5D. As another example, a material layer distinct from the fourth material layer ML4 may be formed on the second material layer ML2a of FIG. 5C, thus forming the second material layer ML2b of FIG. 5D.

Referring to FIG. 5E, a second alignment key AK2 may be formed in the second scribe lane area SLA2 of the second structure STR2. For example, the second alignment key AK2 may be formed in the second alignment key area AKA2 of the second scribe lane area SLA2. The second alignment key AK2 may be the second bonding key BK2 of FIG. 3A.

The second bonding pads BP2 may be formed in the second scribe lane area SLA2 of the second structure STR2. Referring to FIG. 5E, at least one second bonding pad BP2 may be formed between the second alignment key AK2 and the second chip area CHA2. The second bonding pads BP2 may border the upper surface of the second structure STR2. For example, a portion of the upper surface of the second material layer ML2b may be etched to form trenches, and the interior of the trenches may be filled with a metal layer to form the second bonding pads BP2. An anisotropic dry etching process may be performed to form the trenches at designated positions on the second material layer ML2b.

A fourth bonding pad BP4 may be formed in the second chip area CHA2 of the second structure STR2. The fourth bonding pad BP4 may border the upper surface of the second structure STR2. For example, a portion of the upper surface of the fourth material layer ML4 may be etched to form trenches, and the interior of the trenches may be filled with a metal layer to form the fourth bonding pad BP4.

In an embodiment, the second bonding pads BP2 and the fourth bonding pad BP4 may be simultaneously formed. In another embodiment, the second bonding pads BP2 and the fourth bonding pad BP4 may be formed through different processes.

Referring to FIG. 5F, the second structure STR2 may be flipped so that the second bonding pads BP2 borders the lower surface of the second structure STR2. The flipped second structure STR2 may be stacked on the first structure STR1. For example, the second structure STR2 may be stacked on the first structure STR1 so that the second bonding pads BP2 contact the first bonding pads BP1, respectively, and the fourth bonding pad BP4 contacts the third bonding pad BP3.

When the flipped second structure STR2 is stacked on the first structure STR1, the first bonding pads BP1 may overlap with the second bonding pads BP2, respectively. Further, when the flipped second structure STR2 is stacked on the first structure STR1, the fourth bonding pad BP4 may overlap with the third bonding pad BP3.

Further, when the flipped second structure STR2 is stacked on the first structure STR1, the second alignment key AK2 might not overlap with the first alignment key AK1. The first alignment key AK1 may contact the second material layer ML2b, and the second alignment key AK2 may contact the first material layer ML1.

Referring to FIG. 5G, the second substrate SST2 of the second structure STR2 may be removed. After the second substrate SST2 is removed, a portion of the cell plug CP may be exposed. Further, a portion of the exposed cell plug CP may be etched. For example, a blocking layer, a charge trap layer, and a tunnel isolation layer of the exposed portion of the cell plug CP may be removed. Therefore, some areas of the channel layer of the cell plug CP may be externally exposed.

Referring to FIG. 5H, a source layer SL may be formed in the chip area CHA (e.g., the second cell area CHA2 of the second structure STR2 of FIG. 5E). The source layer SL may be formed to enclose the exposed cell plug CR For example, the source layer SL may contact the exposed channel layer.

Further, a second material layer ML2c may be formed in the second scribe lane area SLA (e.g., the second scribe lane area SLA2 of the second structure STR2 of FIG. 5E). For example, a material layer identical to the source layer SL may be formed on the second material layer ML2b of FIG. 5G to form the second material layer ML2c of FIG. 5H. In another embodiment, a material layer distinct from the source layer SL may be formed on the second material layer ML2b of FIG. 5G, thus forming the second material layer ML2c of FIG. 5H.

Referring to FIGS. 5A to 5H, although the alignment key AK of FIG. 2 is shown to be the first and second bonding keys BK1 and BK2 in FIG. 3A, it is merely for convenience of explanation and is not limited thereto. For instance, when the alignment key AK of FIG. 2 is the overlay key OK of FIG. 3B, the second alignment key AK2 may be omitted in FIGS. 5A to 5H. In another embodiment, when the alignment key AK of FIG. 2 is the overlay key OK of FIG. 3C, the first alignment key AK1 may be omitted in FIGS. 5A to 5H.

According to the present disclosure, the first bonding pads BP1 may be simultaneously formed in the first scribe lane area SLA1 during the process of forming the third bonding pad BP3 in the first chip area CHA1. In addition, the second bonding pads BP2 may be simultaneously formed in the second scribe lane area SLA2 during the process of forming the fourth bonding pad BP4 in the second chip area CHA2. That is, the process for forming the first and second bonding pads BP1 and BP2 might not increase the manufacturing time. Therefore, even if the first and second bonding pads BP1 and BP2 are added in the present disclosure, no cost or time may be added during the process of manufacturing the semiconductor device.

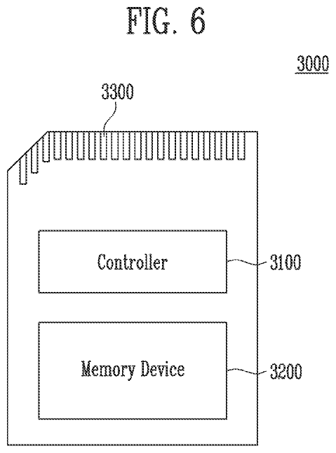

FIG. 6 is a diagram illustrating a memory card system to which the semiconductor device of the present disclosure is applied.

Referring to FIG. 6, a memory card system 3000 may include a controller 3100, a memory device 3200, and a connector 3300.

The controller 3100 may be connected to the memory device 3200. The controller 3100 may access the memory device 3200. For instance, the controller 3100 may control the program, read, or erase operation of the memory device 3200 or may control a background operation. The controller 3100 may provide an interface between the memory device 3200 and a host. The controller 3100 may run firmware for controlling the memory device 3200. For example, the controller 3100 may include components, such as a Random Access Memory (RAM), a processing unit, a host interface, a memory interface, and an error corrector.

The controller 3100 may communicate with an external device through the connector 3300. The controller 3100 may communicate with an external device (e.g., a host) based on a specific communication standard. For example, the controller 3100 may communicate with the external device through at least one of the following various communication standards: universal serial bus (USB), multimedia card (MMC), embedded MMC (eMMC), peripheral component interconnection (PCI), PCI-express (PCI-E), an advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, nonvolatile memory express (NVMe), etc. For example, the connector 3300 may be defined by at least one of the above-described communication standards.

The memory device 3200 may include a plurality of memory cells and may correspond to the semiconductor device according to the present disclosure.

The controller 3100 and the memory device 3200 may be integrated into a single semiconductor device to form a memory card. For example, the controller 3100 and the memory device 3200 may be integrated into the single semiconductor device to form the memory card, such as a PC card (personal computer memory card international association: PCMCIA), a compact flash card (CF), a smart media card (SM, SMC), a memory stick, a multimedia card (MMC, RS-MMC, MMCmicro, eMMC), a SD card (SD, miniSD, microSD, SDHC), or a universal flash storage (UFS).

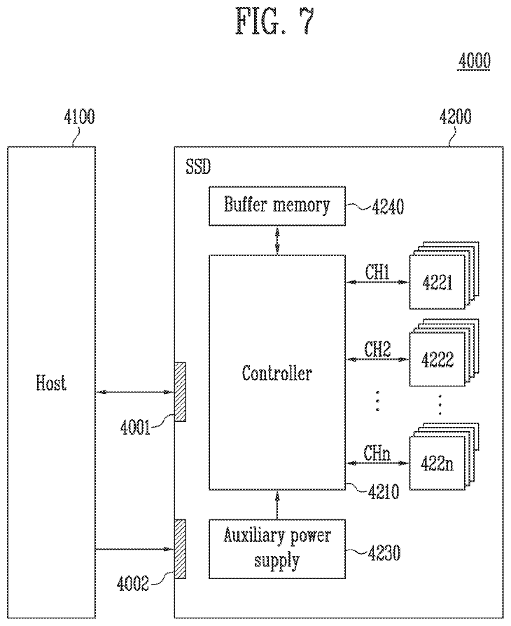

FIG. 7 is a diagram illustrating a Solid State Drive (SSD) system to which the semiconductor device of the present disclosure is applied.

Referring to FIG. 7, an SSD system 4000 may include a host 4100 and an SSD 4200. The SSD 4200 may exchange a signal with the host 4100 through a signal connector 4001 and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to a signal received from the host 4100. For example, the signal may indicate signals based on an interface between the host 4100 and the SSD 4200. For example, the signal may be a signal defined by at least one of the following interfaces: universal serial bus (USB), multimedia card (MMC), embedded MMC (eMMC), peripheral component interconnection (PCI), PCI-express (PCI-E), an advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, nonvolatile memory express (NVMe), etc.

The plurality of memory devices 4221 to 422n may include a plurality of memory cells configured to store data. Each of the plurality of memory devices 4221 to 422n may correspond to the semiconductor device according to the present disclosure. The plurality of memory devices 4221 to 422n may communicate with the controller 4210 through channels CH1 to CHn.

The auxiliary power supply 4230 may be connected to the host 4100 through the power connector 4002. The auxiliary power supply 4230 may receive a supply voltage from the host 4100 and may perform a charge operation. When power is not smoothly supplied from the host 4100, the auxiliary power supply 4230 may provide the supply voltage of the SSD 4200. For instance, the auxiliary power supply 4230 may be located inside the SSD 4200 or outside of the SSD 4200. For example, the auxiliary power supply 4230 may be located on a main board and may supply auxiliary power to the SSD 4200.

The buffer memory 4240 may be operated as the buffer memory of the SSD 4200. For instance, the buffer memory 4240 may temporarily store data received from the host 4100 or data received from the plurality of memory devices 4221 to 422n or may temporarily store meta data (e.g., mapping table) of the memory devices 4221 to 422n. The buffer memory 4240 may include a volatile memory, such as DRAM, SDRAM, DDR SDRAM, or LPDDR SDRAM or may include a nonvolatile memory, such as FRAM, ReRAM, STT-MRAM, or PRAM.

According to the present disclosure, it is possible to increase a bonding force during wafer bonding through a bonding pad formed in a scribe lane area.

What is claimed is:

1. A semiconductor device comprising:
a first structure including a first chip area and a first scribe lane area;
a second structure provided on the first structure;
a first alignment key disposed in the first scribe lane area;
at least one first bonding pad disposed in the first scribe lane area, provided between the first alignment key and the first chip area, the first bonding pad bordering an upper surface of the first structure; and
at least one second bonding pad bordering a lower surface of the second structure to contact the at least one first bonding pad.

2. The semiconductor device according to claim 1,
wherein the second structure comprises a second chip area and a second scribe lane area, and
wherein the at least one second bonding pad is disposed in the second scribe lane area.

3. The semiconductor device according to claim 2, further comprising:
a second alignment key disposed in the second scribe lane area and configured to not overlap with the first alignment key.

4. The semiconductor device according to claim 3,
wherein the first alignment key borders the upper surface of the first structure, and
wherein the second alignment key borders the lower surface of the second structure.

5. The semiconductor device according to claim 1, wherein the at least one first bonding pad is spaced apart from the first alignment key.

6. The semiconductor device according to claim 1, wherein the at least one first bonding pad is disposed in at least one direction from the first alignment key: a first direction, a second direction intersecting the first direction, a direction opposite to the first direction, or a direction opposite to the second direction.

7. The semiconductor device according to claim 1,
wherein the first alignment key is disposed in a first alignment key area of the first scribe lane area, and
wherein the at least one first bonding pad is adjacent to a boundary of the first alignment key area.

8. The semiconductor device according to claim 1, further comprising:
a first bonding pad group including the at least one first bonding pad; and
a second bonding pad group including the at least one second bonding pad.

9. The semiconductor device according to claim 8, wherein the at least one first bonding pad group is disposed along a border of the first alignment key.

10. The semiconductor device according to claim 1, wherein the at least one first bonding pad and the at least one second bonding pad overlap with each other.

11. The semiconductor device according to claim 1, wherein the at least one first bonding pad and the at least one second bonding pad comprise identical material.

12. The semiconductor device according to claim 1, wherein the at least one first bonding pad and the at least one second bonding pad comprise different materials.

13. The semiconductor device according to claim 1, wherein the first alignment key is a bonding key or an overlay key.

14. The semiconductor device according to claim 2, further comprising:
a third bonding pad provided in the first chip area, the third bonding pad bordering the upper surface of the first structure; and
a fourth bonding pad provided in the second chip area, the fourth bonding pad bordering the lower surface of the second structure to contact the third bonding pad.

15. The semiconductor device according to claim 14, wherein the first to fourth bonding pads comprise identical material.
